(19) United States
(12) Patent Application Publication
(10) Pub. No.: US 2014/0218873 A1
(43) Pub. Date: Aug. 7, 2014

(54) SYMMETRICAL FLAT PANEL DISPLAY

(71) Applicant: MOTOROLA MOBILITY LLC, Libertyville, IL (US)

(72) Inventors: XiaoPing Bai, Lake Zurich, IL (US); John W. Kaehler, Mundelein, IL (US); Weihong Zhang, Kildeer, IL (US); Zhiming Zhuang, Palatine, IL (US)

(73) Assignee: MOTOROLA MOBILITY LLC, Libertyville, IL (US)

(21) Appl. No.: 14/166,277

(22) Filed: Jan. 28, 2014

Related U.S. Application Data
(60) Provisional application No. 61/757,567, filed on Jan. 28, 2013.

(51) Int. Cl. H05K 1/11

(52) U.S. Cl. CPC H05K 1/118; H05K 2201/05
USPC 361/749

(57) ABSTRACT

A display includes an encapsulation layer and a substrate. The substrate includes a chip on glass (COG) seat and a flexible printed circuit (FPC) connector seat. The COG seat and the FPC seats are positioned on different edges of the substrate. A cross-connection layer between the substrate layer and the encapsulation layer, the cross-connection layer including traces connected between the COG seat and the FPC seat. A device incorporating the display may take advantage of the symmetrical display to achieve new designs.

### TECHNICAL FIELD

This invention relates generally to electronic displays for portable electronic devices.

### BACKGROUND

“Intelligent” portable electronic devices, such as smart phones, tablet computers, and the like, are becoming increasingly powerful computational tools. Today, “smart” phones, tablet computers, personal digital assistants, and other portable electronic devices not only make telephone calls, but also manage address books, maintain calendars, play music and videos, display pictures, and surf the web. As the capabilities of these electronic devices have progressed, so too have their user interfaces. Displays including touch sensitive systems, such as touch sensitive displays, touch sensitive pads, and the like, include sensors for detecting the presence of an object such as a finger or stylus. By placing the object on the touch sensitive system, the user can manipulate and control the electronic device without the need for a physical keypad.

One enhancement associated with these touch sensitive systems concerns the user experience. Many applications today are being designed to primarily function with an electronic device having a large display surface. In addition, manufacturers are striving toward an edge-to-edge experience in which the entire front surface of a device display contains usable content. However, displays limit the flexibility of designers. An improved electronic display is needed offering designers enhanced flexibility in designing a device without compromising the enhanced user experience.

### BRIEF DESCRIPTION OF THE DRAWINGS

FIG. 1 illustrates a PRIOR ART display.

FIG. 2 illustrates one example display.

FIG. 3 illustrates an example electronic circuit trace for the display according to FIG. 2.

FIG. 4 illustrates an example display panel structure cross-section view through plane 4-4 of FIG. 2.

FIG. 5 illustrates another example display panel structure cross-section view through plane 5-5 of FIG. 2.

FIG. 6 illustrates another example of a display showing different ledge cuts.

FIG. 7 illustrates a prior art device incorporating a display.

FIG. 8 illustrates a device incorporating a display according to the examples herein.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

Apparatus components and method steps, if any, have been represented where appropriate by conventional symbols in the drawings, showing only those specific details that are pertinent to understanding the several embodiments so as not to obscure the disclosure with details that will be readily apparent to those of ordinary skill in the art having the benefit of the description herein. Any process descriptions, or blocks in flow charts, should be understood as representing modules, segments, or portions of code that include elements or one or more executable instructions for implementing specific components, logical functions, or steps in the process. Any applicable implementations are included, and it will be clear that functions may be executed out of order from that shown or discussed, including substantially concurrently or in reverse order, depending on the functionality involved.

A competitive mobile computing device marketplace for items such as smartphones, tablet computers, wearable computing devices, for example, causes designers of these devices to seek innovation in many different aspects. Display design can be an important aspect of any innovative design. For example, smartphone displays that incorporate edge-to-edge designs offer a user a differentiated look and feel.

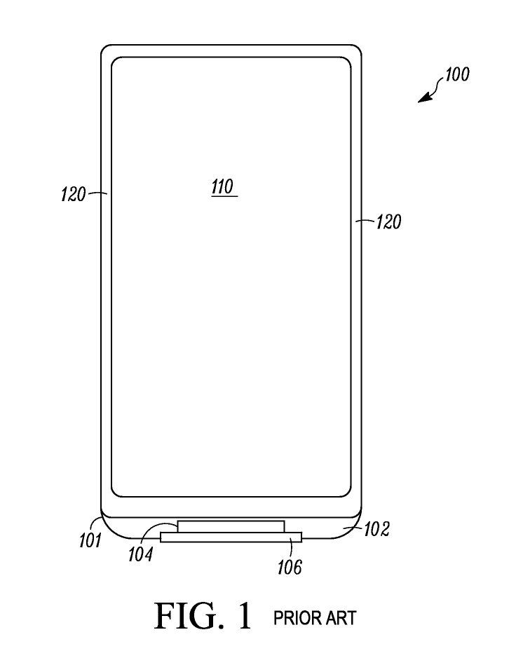

FIG. 1 shows a conventional display 100 having an asymmetric display. Conventional display designs include an asymmetric display in a Y-direction, with a ledge 102 of the TFT layer 101, supporting a driver IC seat for chip on glass (COG) bonding and at least one connector seat for flexible printed circuit (FPC) bonding, and extending the length of the display on one end. Such extension may restrict and undesirably limit a device designer's attempt to offer a centralized display. The bonding ledge 101 at the bottom of the display makes the bottom border more than 3× bigger than the border at the top of the display. Furthermore, a larger COG ledge may be subject to cracked glass during manufacturing and testing. The ledge 101 can be located at either end of the display.

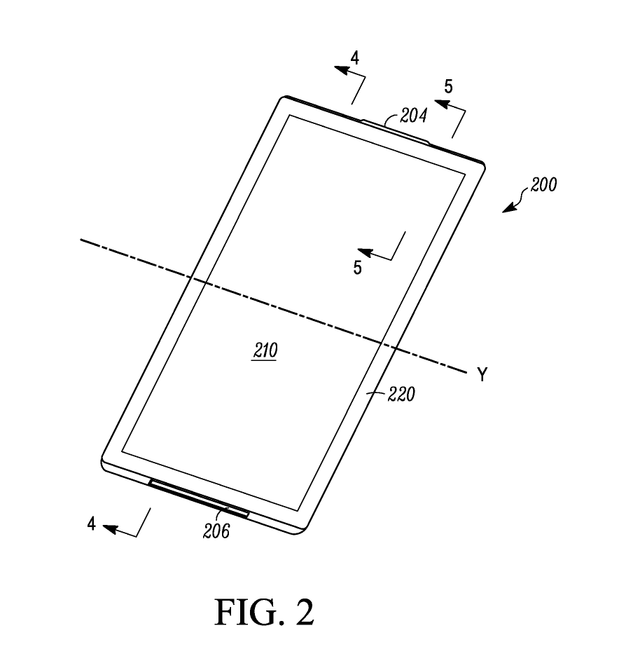

FIG. 2 shows a display assembly 200 that employs a separation of the COG driver IC seat 204 and the FPC connector seat 206 by locating each different ends of the display. One embodiment of an improved display incorporates a COG seat at a bottom end of the display and a FPC connector seat at the top end of the display. A cross-connection layer of electronic circuit traces is carried above a thin-film transistor (TFT) substrate and below an emission layer to support the FPC and COG seats at opposite ends. Separation of the bonding seats enables a centralized display design with a small, even border at each end of the display.

FIG. 1 shows a conventional display 100 having an asymmetric display. The TFT layer 101 includes a bonding ledge 102 that carries the COG seat 104 for a driver IC and an FPC seat for an FPC connector 106. The flex connector and the driver IC are bonded to the TFT layer 101 at the FPC connector seat and the COG flex seat, respectively. The shared ledge 102 for FPC bonding and COG bonding is located at the bottom, or top, of the display. A first gap is provided between the active area 110 of the display and the driver IC seat 104, and a second gap is provided between driver IC seat 104 and the FPC seat for FPC connector 106. The gaps provided for the driver IC seat 104 and the FPC seat provide necessary spacing to accommodate flex traces between the driver IC and the flex connector, and protect the circuit and TFT layer from damage during manufacture. The display includes a border 120 circumscribing the active area 110 as is known in the art.

FIG. 2 shows a display 200 with separation of the COG driver IC seat 204 at a top of the display and the FPC connector seat 206 at a bottom of the display. Alternatively, the driver IC seat 204 could be positioned at the bottom and the FPC seat at the top. The separation of the COG seat 204 and the FPC seat 206 makes the display configuration symmetric around the center axis Y, in the Y-direction. Additionally, moving the driver IC seat 204 and the FPC seat 206 to opposite ends of electronic device eliminates the need for the gap between the driver IC and FPC seats in the prior art of FIG. 1. This advantage may usable to reduce the over all length of the display.

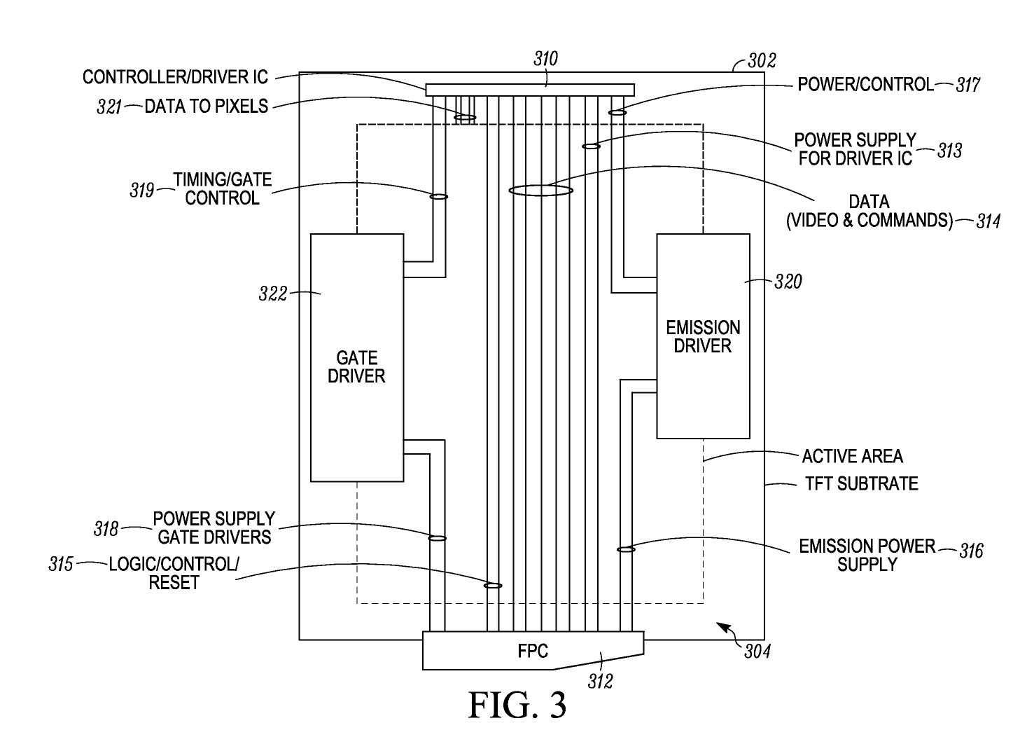

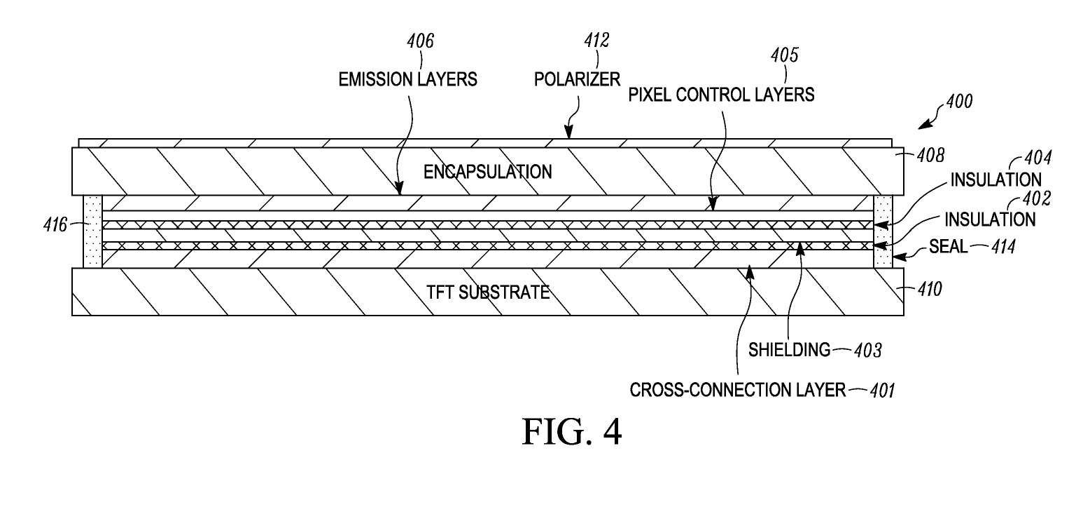

FIG. 3 shows an electrical cross-connection circuit 304 on the TFT substrate 302, the cross-connection 304 between the driver IC 310 and the FPC connector 312. As illustrated in FIG. 3, the cross-connection includes traces 313 for the power supply for the driver IC, data (including video and commands) traces 314, and logic/control/reset traces 315. The emission power supply 316 for the emission driver 320 is received from the FPC connector 312. The emission driver power control 317 traces connect to the driver IC 310. The power supply 318 traces to the gate driver 322 are connected to FPC connector 312. The gate driver 322 timing/gate control signals are connected to the driver IC 322 by traces 319. The driver IC 310 connects to the pixel-by-pixel traces 321. The emission driver and the gate driver are positioned in the emission layer FIG. 4, and are connected to the cross-connector layer 304 through vias (not shown). The traces in the display are conductive, and the total number of traces in the display may number in the several thousands. These traces may block light transmission, so the display may advantageously be an OLED display, or other display type that is self-light emissive or illuminated from the front. It is envisioned that a MEMs display may be employed if sufficiently small traces are used with sufficient lighting. It is also envisioned that the display may be a reflective-type display using front light.

FIG. 3 shows the FPC and the driver IC in a portrait display with the driver IC and FPC connector positioned on the relatively shorter ends of the display, and the emission driver 320 and gate driver 320 on the longer sides. It is envisioned that the display may be a landscape display, with the emission and gate drivers located on the relatively longer ends, and the gate driver and emission driver on the shorter sides.

The structure of the display 400 is further described with reference to FIG. 4. The display panel structure includes the cross-connection layer 401, an electrical insulation layer 402, an electrical shield 403, an electrical insulation layer 404, a pixel control layer 405, and an emission layer 406 (for an example OLED display), between the front encapsulation layer 408 and the TFT substrate 410. An optional polarizer 412 is carried on the front surface of the encapsulation layer. A seal 414, 416 may be provided around the layers of the display between the substrate 410 and the encapsulation 408. The gate driver and an emission driver (not shown in FIG. 4) are positioned in the driver emission layer and connected to traces in the cross-connection layer 401 by vias (not shown).

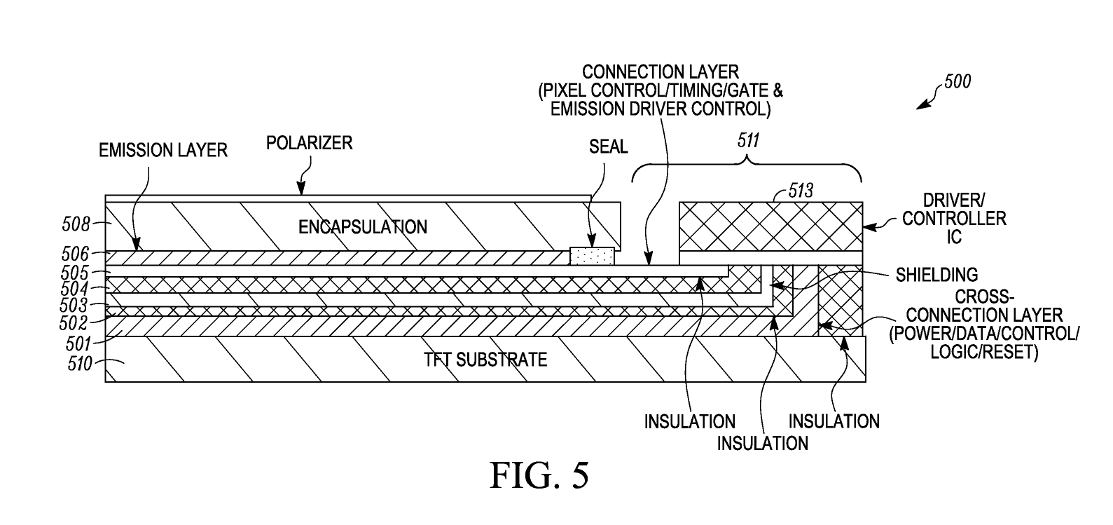

FIG. 5 illustrates the display 500 including panel ledge 511, of TFT substrate 510, for driver IC 513. The cross-connection layer 501, electrical insulation layer 502, electrical shield 503, electrical insulation layer 504, a pixel control layer 505, and emission layer 506 (for the example OLED display) are between the front encapsulation layer 508 and the TFT substrate 510. The driver IC 513 on ledge 511 connects to the cross-connect layer 501 and connection layer 505. Connection to the emission layer 506 is from the cross-connection layer 501 through vias, and/or optionally through the connection layer 505. The driver IC connects to the cross-connection layer to receive power, data, logic, or control signals, or a combination thereof, and preferably all of these signals, and any other signals that enable operation of the display. The driver IC 513 may also communicate with other components via other layers, to make the display operational.

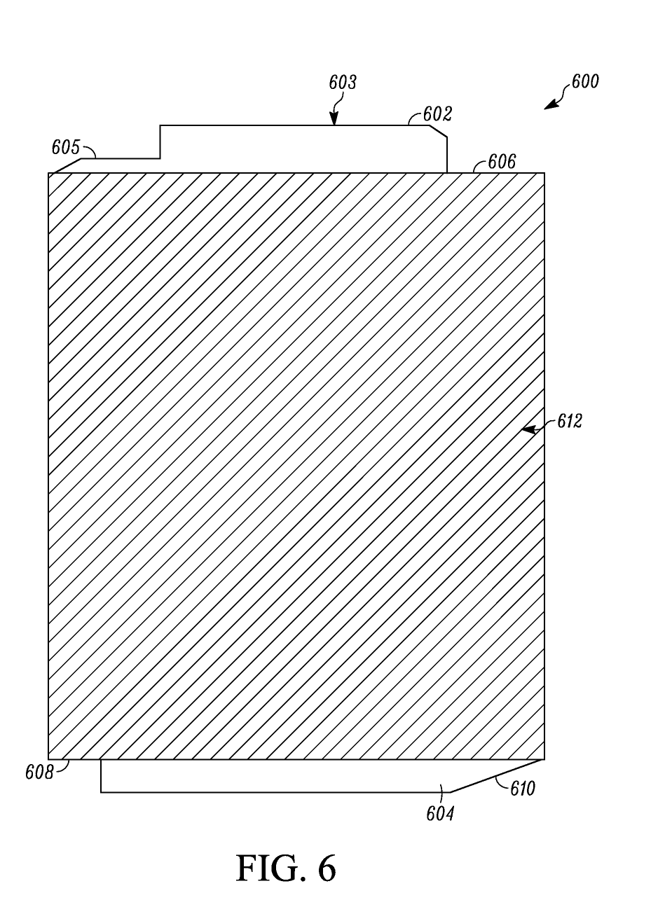

FIG. 6 illustrates a display 600 including COG bonding ledge 602 and FPC ledge 604 in TFT substrate 603. The front encapsulation 612 is illustrated covering the TFT layer, with the ledges 602 extending beyond the front encapsulation. The laser cut outs 605, 606, 608, and 610 are shown having different shapes to illustrate the flexibility available to assist the designer in positioning the display in a device. The cuts may be made by any suitable known means, such as laser cutting. The cut outs can be used to accommodate other components in a device incorporating the display, such as electrical components and mechanical fasteners, such as those used to assemble the device housing around the display. Additionally, these cutouts may enable greater flexibility to the designer in reducing the overall length of the device and achieving closer to the edge active display region. The cutouts may symmetrical, or asymmetrical, as needed, and may range from 0 degrees to 90 degrees.

The display according to FIGS. 2 through 6 removes a major obstacle to achieving a compact edge-to-edge centralized display. Eliminating the physically large combined COG and FPC bonding ledge used in conventional designs yields an asymmetric display around the Y axis. Additionally, by separating the COG and FPC bonding ledge, each ledge is smaller than the combined ledge of the display 100 (FIG. 1), which improves manufacturing yield and reliability by reducing cracking.

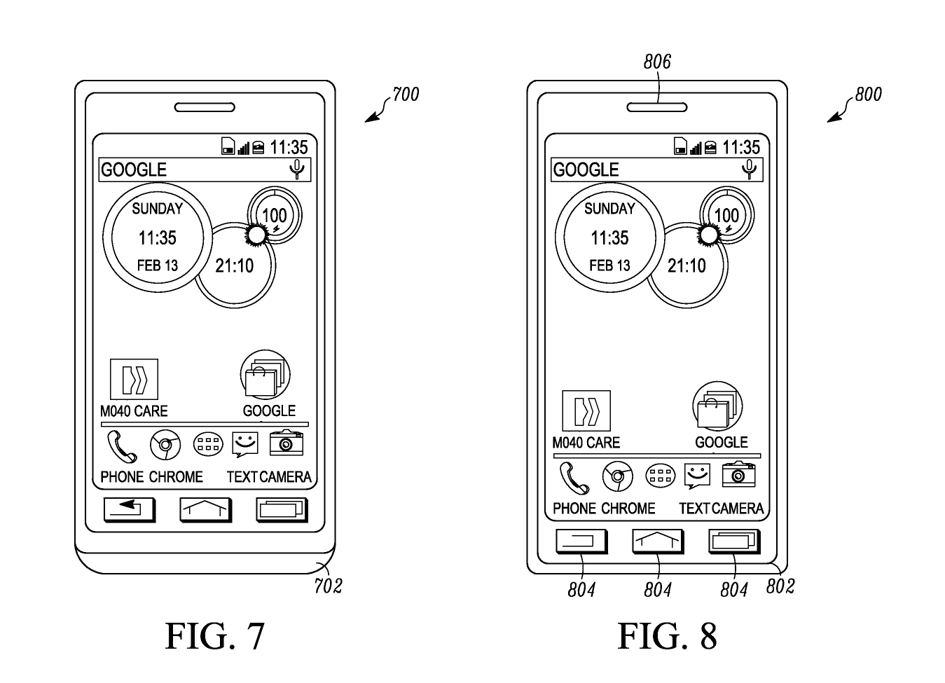

FIG. 7 illustrates a PRIOR ART device 700 incorporating a display 100 according to FIG. 1, and including a wide chin 702 at a bottom area. This area in the extended chin to accommodate the large ledge of display 100 (FIG. 1) can not be used for active display pixels. FIG. 8 illustrates a device 800 including a display incorporating display 200 (FIG. 2) and including a significantly smaller lower housing extension below the active display pixels. Still smaller housings are enabled by the improved displays described herein. Additionally, the display 200 can extend the active area of the display down to the border 802 by eliminating the keys 804 and up to the speaker port 806.

It will be appreciated that embodiments described herein may be comprised of one or more conventional processors and unique stored program instructions that control the one or more processors to implement, in conjunction with certain non-processor circuits, some, most, or all of the functions of methods for detecting interactive applications operating on remote devices, presenting control interfaces to control the interactive applications on a local device, and communicating control input received at the local device to the remote device as described herein. The non-processor circuits may include, but are not limited to, a radio receiver, a radio transmitter, signal drivers, clock circuits, power source circuits, and user input devices. As such, these functions may be interpreted as steps of a method to perform control of an interactive application operating on a remote device by presenting a control interface on a local device, receiving user input, and communicating the user input to the remote device. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used. Thus, methods and means for these functions have been described herein.

Further, it is expected that one of ordinary skill, notwithstanding possibly significant effort and many design choices motivated by, for example, available time, current technology, and economic considerations, when guided by the concepts and principles disclosed herein, will be readily capable of generating such software instructions and programs and ICs with minimal experimentation. One or more embodiments are now described in detail.

As used in the description herein and throughout the claims, the following terms take the meanings explicitly associated herein, unless the context clearly dictates otherwise: the meaning of “a,” “an,” and “the” includes plural reference, the meaning of “in” includes “in” and “on.” Relational terms such as first and second, top and bottom, and the like may be used solely to distinguish one entity or action from another entity or action without necessarily requiring or implying any actual such relationship or order between such entities or actions.

Thus, while several embodiments of the disclosure have been illustrated and described, it is clear that the innovative concept is not so limited. Numerous modifications, changes, variations, substitutions, and equivalents will occur to those skilled in the art without departing from the scope of the present invention as defined by the following claims. Accordingly, the specification and figures are to be regarded in an illustrative rather than a restrictive sense, and all such modifications are intended to be included within the scope of present invention. The benefits, advantages, solutions to problems, and any element(s) that may cause any benefit, advantage, or solution to occur or become more pronounced are not to be construed as a critical, required, or essential features or elements of any or all the claims.

We claim:

1. An display comprising:
an encapsulation layer;
a substrate, the substrate including a chip on glass (COG) seat and a flexible printed circuit (FPC) connector seat, the COG seat and the FPC seats on different edges of the substrate; and
a cross-connection layer between the substrate layer and the encapsulation layer, the cross-connection layer including traces connected between the COG seat and the FPC seat.

2. The display according to claim 1, wherein the substrate includes a COG ledge for the COG seat.

3. The display according to claim 1, wherein the substrate includes a FPC ledge for the FPC seat.

4. The display according to claim 2, wherein the substrate includes a FPC ledge for the FPC seat.

5. The display according to claim 4, wherein the FPC ledge for the COG ledge have different shapes.

6. The display according to claim 1, further including an emission layer between the cross connection layer and the encapsulation.

7. The display according to claim 2, further including a pixel layer between the emission layer and the cross-connection layer.

8. The display according to claim 1, further including a driver IC bonded to the COG seat.

9. The display according to claim 1, further including a connector bonded to the FPC seat.

10. The display according to claim 6, further including drivers in the emission layer connected to the cross-connection layer.

11. A device comprising:
a housing;
a display carried in the housing, the display including
an encapsulation layer,
a substrate, the substrate including a chip on glass (COG) seat and a flexible printed circuit (FPC) connector seat, the COG seat and the FPC seats on different edges of the substrate, and
a cross-connection layer between the substrate layer and the encapsulation layer, the cross-connection layer including traces connected between the COG seat and the FPC seat.

12. An display comprising:
an encapsulation layer; and
a substrate layer, the substrate layer including a chip on glass (COG) seat ledge and a flexible printed circuit (FPC) ledge, the COG seat and the FPC seats on different edges of the substrate outside the active area of the display.
